(19) United States
(12) Patent Application Publication
(10) Pub. No.: US 2008/0094149 A1
(43) Pub. Date: Apr. 24, 2008

(54) POWER AMPLIFIER MATCHING CIRCUIT AND METHOD USING TUNABLE MEMS DEVICES

(75) Inventor: Michael Brobston, Allen, TX (US)

Correspondence Address: TIMOTHY F. BLISS, P.O. BOX 793968, DALLAS, TX, 75379-3968, US

(73) Assignee: Sungsung Electronics Co., Ltd., Suwon-si (KR)

(21) Appl. No.: 11/957,606

(22) Filed: Dec. 17, 2007

Related U.S. Application Data
(63) Continuation-in-part of application No. 11/232,663, filed on Sep. 22, 2005, now Pat. No. 7,332,980.

(51) Int. Cl. H03H 7/40

(52) U.S. Cl. 333/17.3

(57) ABSTRACT

The present disclosure relates to a power amplifier circuit. In one example, the power amplifier circuit includes a power amplifier coupled to a variable load and a digitally tunable impedance matching network (TMN) positioned between the power amplifier and the variable load. The TMN includes at least one controllable capacitor having a maximum capacitance CT, where the controllable capacitor has a plurality of actuable capacitive elements having differing reactance values ranging from CT*2⁰ to CT*2^{N}, where N=>1.

### CLAIM OF PRIORITY AND CROSS-REFERENCE TO RELATED APPLICATIONS

This application is a continuation-in-part of U.S. patent application Ser. No. 11/232,663, filed on Sep. 22, 2005 and entitled SYSTEM AND METHOD FOR A DIGITALLY TUNABLE IMPEDANCE MATCHING NETWORK”, which is incorporated herein in its entirety.

This application is related to U.S. patent application Ser. No. 11/404,734, filed on Apr. 14, 2006, entitled SYSTEM AND METHOD FOR A TUNABLE IMPEDANCE MATCHING NETWORK”, which is incorporated herein in its entirety.

### BACKGROUND

Impedance matching is used to match the impedance of a source with the impedance of a load circuit. As is known, matching the impedance of the source and load enables the maximum amount of power to be transferred from the source to the load for a given signal. However, power amplifier impedance matching presents particular difficulties in mobile devices, such as mobile handsets that may be able to operate over multiple frequency bands.

Therefore, what is needed is a new and improved system for impedance matching in a mobile device and a method for using such a system.

### SUMMARY

In one embodiment, a handset comprises a power amplifier, a variable load, a digitally tunable impedance matching network, a processor, and a memory. The digitally tunable impedance matching network is positioned between the power amplifier and the variable load. The digitally tunable impedance matching network includes a first controllable capacitor having a maximum capacitance CT, wherein the first controllable capacitor has a plurality of actuable capacitive elements having differing reactance values ranging from CT*2⁰ to CT*2^{N}, where N=>1. The processor is coupled to the digitally tunable impedance matching network and configured to actuate individual ones of the plurality of capacitive elements to produce a reactance of CT*2⁰ to CT*2^{N}. The memory is coupled to the processor and includes a plurality of predefined configurations designed for use by the processor in actuating individual ones of the plurality of capacitive elements to produce a reactance of CT*2⁰ to CT*2^{N} in response to a current operating condition of the handset.

In another embodiment, a power amplifier circuit comprises a power amplifier coupled to a variable load and a digitally tunable impedance matching network positioned between the power amplifier and the variable load. The digitally tunable impedance matching network includes a first controllable capacitor having a maximum capacitance CT, wherein the first controllable capacitor has a plurality of actuable capacitive elements having differing reactance values ranging from CT*2⁰ to CT*2^{N}, where N=>1.

In still another embodiment, a method for controlling a digitally tunable impedance matching network for a power amplifier in a handset comprises identifying a matching impedance needed to match a target impedance for the power amplifier and obtaining a plurality of settings of the digitally tunable impedance matching network needed for the digitally tunable impedance matching network to produce the matching impedance from a look up table. The method also includes sending signals to actuators associated with capacitive elements of the digitally tunable impedance matching network based on the plurality of settings, and actuating the capacitive elements using the actuators to substantially produce the matching impedance using the digitally tunable impedance matching network.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a diagram of a system containing digitally tunable matching networks for matching the impedance of various components.

FIG. 2 is a circuit diagram of one embodiment of a capacitor-based digitally tunable matching network that may be used within the system of FIG. 1.

FIG. 3 is a flowchart of a method that may be executed within the system of FIG. 1 for impedance matching.

FIG. 4 is a perspective view of one embodiment of a microelectromechanical system (MEMS) that may be used to form one of the capacitors within the digitally tunable matching network of FIG. 2.

FIG. 5a is a side view of the MEMS of FIG. 4 in a non-actuated state.

FIG. 5b is a side view of the MEMS of FIG. 4 in an actuated state.

FIG. 6 is an overhead view of a capacitor-based digitally tunable matching network implementation of the circuit of FIG. 2 using a plurality of the MEMS of FIG. 4.

FIG. 7 is a circuit diagram of another embodiment of a capacitor-based digitally tunable matching network that may be used within the system of FIG. 1.

FIG. 8 is an overhead view of a capacitor-based digitally tunable matching network implementation of the circuit of FIG. 7.

FIG. 9 is a circuit diagram of an embodiment of an inductor-based digitally tunable matching network that may be used within the system of FIG. 1.

FIG. 10a is a diagram illustrating the use of multiple matching networks in a multi-band power amplifier environment.

FIG. 10b is a diagram illustrating the use of a single digitally tunable impedance matching network in place of the multiple matching networks of FIG. 10a.

FIG. 11 is a diagram illustrating the use of a digitally tunable impedance matching network for impedance matching an amplifier in a variable load line environment.

FIG. 12 is an exemplary chart illustrating load line variations based on bias current and/or bias voltage changes.

FIG. 13a is a diagram illustrating the use of multiple matching networks in a multi-band low noise amplifier environment.

FIG. 13b is a diagram illustrating the use of a single digitally tunable impedance matching network in place of the multiple matching networks of FIG. 13a.

FIG. 14 is a diagram illustrating a more detailed example of FIG. 11.

FIG. 15 is a circuit diagram of an embodiment of a capacitor-based digitally tunable matching network that may be used within the environment of FIG. 14.

FIG. 16 is a diagram illustrating an alternative embodiment of FIG. 14.

FIG. 17 is a diagram illustrating a control mechanism that may be used with the embodiment of FIG. 14.

FIG. 18 is a flowchart of a method that may be executed within the system of FIG. 14 for impedance matching.

### DETAILED DESCRIPTION

It is to be understood that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

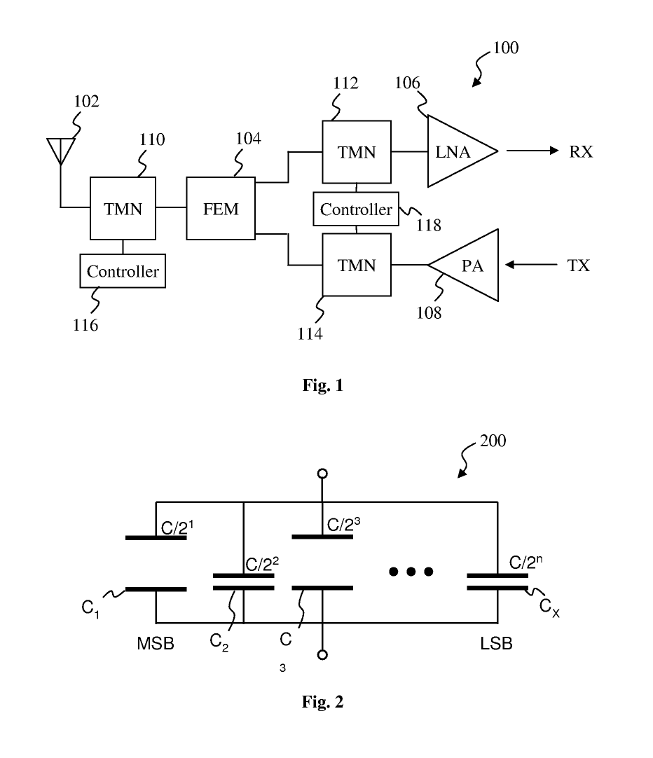

Referring to FIG. 1, in one embodiment, a system 100 is configured to provide for the transmission and reception of information via an antenna 102. For example, the system 100 may be integrated into a mobile handset (e.g., a cell phone) capable of transmitting voice and/or data in a wireless network utilizing a technology such as Code Division Multiple Access (CDMA), Global System for Mobile communication (GSM), Orthogonal Frequency Division Multiplexing (OFDM), or similar communications technologies.

In addition to the antenna 102, the system 100 includes a front-end module (FEM) 104, a low noise amplifier (LNA) 106, and a power amplifier (PA) 108. The antenna 102, FEM 104, and LNA 106 are coupled to form a reception channel whereby data and voice communications received via the antenna 102 are directed to other circuitry (not shown) within the system 100. Similarly, the PA 108, FEM 104, and antenna 102 are coupled to form a transmission channel whereby data and voice communications are sent from other circuitry (not shown) within the system 100 for transmission via the antenna 102.

In some environments, such as a cell phone handset, the system 100 is generally designed to have its radio frequency (RF) transmit/receive impedance match the impedance of the antenna 102 based on a non-reflective environment. In most realistic handset environments the RF impedance may change over time and may vary greatly from that of the non-reflective environment due to factors such as the location of walls, ceilings, or other reflective objects, whether the handset is placed close to the head, the location of the user's fingers relative to the antenna 102, and whether the handset is a flip phone or a slider phone that is closed. Such conditions, which can affect handset performance and quality of communication, may be viewed in terms of their impact on the voltage standing wave ratio (VSWR), which measures the efficiency of an antenna system in terms of the energy that is projected by the system and the energy reflected back to the antenna.

More specifically, a poor VSWR is associated with performance degradation in the handset due to the impedance mismatch between the FEM 104, LNA 106, and PA 108. For example, a change in source or load impedance seen by a duplexer within the FEM 104 can cause power loss and detune the duplexer response. A source impedance mismatch from the antenna 102 as seen by the LNA 106 can result in noise figure degradation in the LNA, which may result in sensitivity degradation. Likewise, load impedance variation seen by the PA 108 can result in power loss and linearity degradation. Degradation in linearity in the PA 108 may result in a degraded adjacent channel power ratio (ACPR), which may cause the handset to fail to comply with various regulatory agency or standards requirements.

Generally, a fixed antenna matching network is unable to adapt and provide sufficient impedance matching of the antenna 102 into the radio front-end components such as the FEM 104, LNA 106, and PA 108. Furthermore, the use of variable reactive elements (e.g., variable capacitors implemented using discrete semiconductor varactors, digitally tunable ferroelectric dielectric ceramics, or a discrete capacitor array controlled using switches), fail to adequately match the impedance.

Accordingly, the system 100 includes three digitally tunable matching networks 110, 112, and 114. It is understood that the digitally tunable matching networks 110, 112, and 114 may be implemented as a single network or as additional, smaller networks if desired, and are presented in the present example as three separate networks for purposes of illustration only. As will be described later in greater detail, the digitally tunable matching networks 110, 112, and 114 each operate to match the impedance between components of the system 100. More specifically, the digitally tunable matching network 110 is configured to match the impedance between the antenna 102 and FEM 104, the digitally tunable matching network 112 is configured to match the impedance between the FEM 104 and LNA 106, and the digitally tunable matching network 114 is configured to match the impedance between the FEM 104 and the PA 108.

As will be described below in greater detail with specific examples, each of the digitally tunable matching networks 110, 112, and 114 includes multiple reactive (e.g., reactance producing) elements that may be switched between two states: ON and OFF. Each of the reactive elements in a single digitally tunable matching network is related to the other reactive elements in the network based on a 2ⁿ relationship. More specifically, a digitally tunable matching network has a maximum capacitive or inductive value MAX, and the reactive elements approximate that value when all of them are ON. The largest reactive element is approximately equal to the maximum value divided by a predefined factor (e.g., 21), and the values of the remaining elements sequentially decrease by the predefined factor. For example, eight reactive elements may have the values of MAX/21, MAX/2², MAX/2³, MAX/2⁴, MAX/2⁵, MAX/2⁶, MAX/2⁷, and MAX/2⁸. Controlling the state of the different reactive elements enables reactance values in the range of approximately MAX/2⁸ to MAX to be selected in steps of MAX/2⁸. Accordingly, adding more reactive elements to such a digitally tunable matching network may permit a greater resolution (as MAX/2ⁿ is smaller) during impedance matching. Although the following examples use a single type of reactive element (either capacitors or inductors), it is understood that some embodiments may include both capacitors and inductors.

Two digital controllers 116 and 118 may be used to provide control signals to the digitally tunable matching networks 110, 112, and 114. It is understood that a single digital controller may control multiple digitally tunable matching networks (as with the controller 118), or a controller may control a single digitally tunable matching network (as with the controller 116). Furthermore, a controller may be integrated with a digitally tunable matching network or with another component, or may be a stand alone controller as illustrated. Such controllers may be programmable, enabling the use of a single controller architecture for different types of matching networks, or may be customized for a particular network type (e.g., as an application specific integrated circuit (ASIC)). The controller may contain the capability to detect and measure the magnitude and/or phase of signal reflections and use these measurements to determine the appropriate capacitor and/or inductor values to select in the matching network. In addition, a controller may perform various calculations (e.g., to identify which capacitors or inductors of a matching network should be used to match a particular impedance) or may simply receive instructions such as ON/OFF from another component and tune the matching network based on those instructions.

Referring to FIG. 2, a circuit 200 illustrates one embodiment of a digitally tunable matching network. In the present example, the circuit 200 is based on digitally tunable capacitors C₁, C₂, C₃, . . . , C_{X} that may be either ON or OFF. Each capacitor C₁, C₂, C₃, . . . , C_{X} is coupled in parallel to the other capacitors and has a predefined capacitive value that is related to the other capacitor values based on a 2ⁿ relationship. More specifically, the entire matching network is designed to have an overall capacitive value of C when all of the capacitors C₁, C₂, C₃, . . . , C_{X} are ON. The largest capacitor in the network (the capacitor C₁) has a capacitive value of C/2 (or C/2ⁿ where n=1). Each capacitor decreases in capacitive value by a fixed amount, such as a factor of 2, and the smallest capacitor in the network (the capacitor C_{X}) provides the resolution of the network (e.g., the smallest amount by which the capacitive value can be increased or decreased). For example, if the capacitor C_{X} has a value of C/2ⁿ and n=8, then the smallest step size of capacitance allowed by the network is 1/256 of C. Therefore, the circuit 200 can provide a range of capacitances from approximately C/256 to C in steps of C/256. It is understood that C may be selected to be a slightly larger value than desired for the total capacitance, as the above example may actually provide a maximum capacitance of C−(C/256), rather than C, depending on the exact capacitor values as manufactured. Furthermore, it is understood that the designation of the overall capacitive value as C is for purposes of example only, and the designation of C may be altered. For example, the overall capacitive value C may be represented as 2C, which means that the largest capacitor has a value of C, rather than C/2.

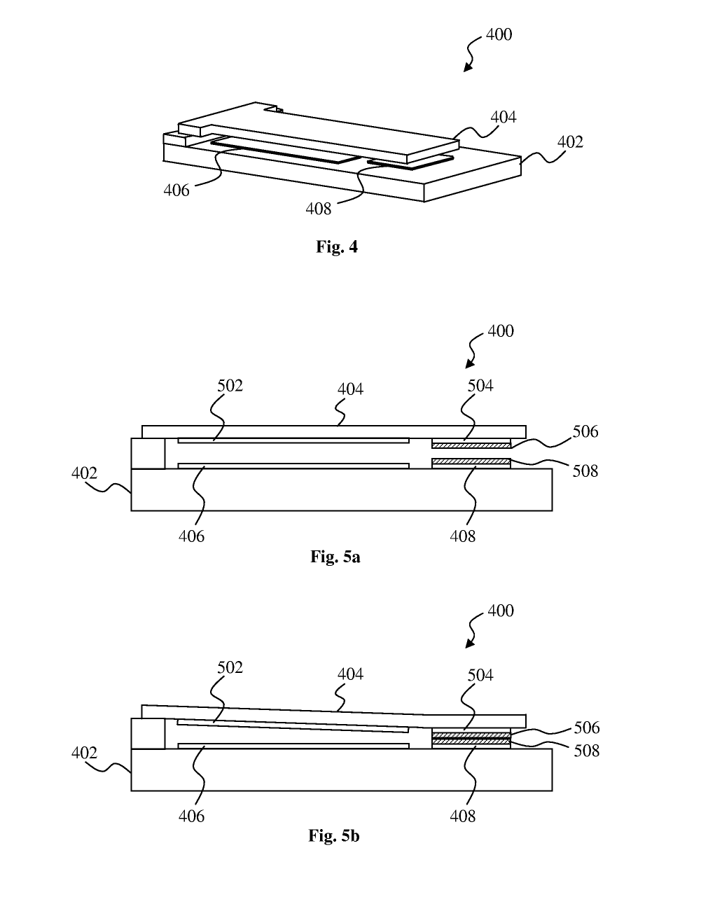

In the present example, the capacitors C₁, C₂, C₃, . . . , C_{X} are controlled according to a binary array, with the largest capacitor C₁ controlled by the most significant bit (MSB) and the smallest capacitor C_{X} controlled by the least significant bit (LSB). As will be described below with respect to FIG. 4, each capacitor is implemented so that the capacitor either contributes to the capacitive network (ON) or does not contribute to the capacitive network (OFF). Therefore, the state of each capacitor may be viewed as a binary switch with the value of each bit representing a capacitor indicating whether the corresponding capacitor is ON or OFF. Furthermore, this binary representation may be used to calculate the capacitance by representing OFF using a zero and ON using a one (or vice versa). Accordingly, referring to FIG. 2, assuming that C¹ and C³ are OFF and C² and C₄ are ON, then the calculation of capacitance for the four capacitors shown in FIG. 2 may be (0*C/2)+(1*C/2²)+(0*C/2³)+(1*C/2n)=C/4+C/2ⁿ.

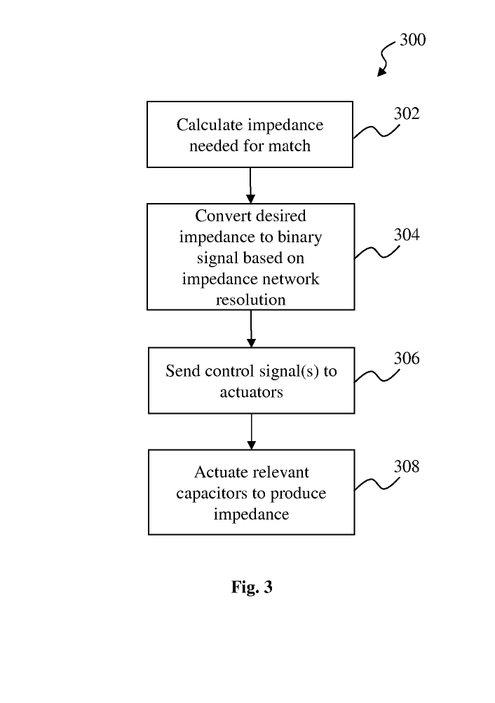

Referring to FIG. 3, a method 300 illustrates one embodiment of a method that may be used within the circuit of FIG. 3 to provide a matching impedance. In step 302, an impedance needed for a match is calculated. For example, the method 300 may be executed to calculate an impedance needed to match the FEM 104 of FIG. 1 with the antenna 102. In step 304, the desired impedance is converted to a binary signal based on the impedance network's resolution. Using the circuit of FIG. 2 as an example, the desired impedance would be calculated based on a resolution of C/2ⁿ.

In step 306, a control signal (or multiple control signals depending on the specific implementation) is sent to an actuator associated with each of the capacitors that is to be turned on. For the example described with respect to FIG. 2 where a capacitance of C/4+C/2ⁿ was desired, such a signal may be a binary signal 0101, indicating the capacitors C₂ and C_{X} are to be turned on (or remain on) and the capacitors C₁ and C₃ are to be turned off (or remain off). In step 308, the relevant actuators are used to turn on their associated capacitor and produce the desired impedance.

Referring to FIG. 4, one embodiment of a digitally tunable capacitor 400 is illustrated. The digitally tunable capacitor 400 is a microelectromechanical system (MEMS) and may be implemented on a substrate 402. Microelectromechanical systems (MEMS) integrate mechanical elements with electronic elements on a common semiconductor substrate using microfabrication technology. For example, the electronic components may be fabricated using CMOS, Bipolar, or BICMOS semiconductor manufacturing processes while the mechanical elements may be fabricated by micromachining processes that selectively etch away parts of the semiconductor wafer or add new structural layers. The digitally tunable capacitor 400 includes a cantilever 404 that extends over an actuator plate 406 and a stationary capacitor plate 408. The cantilever 404 may be rigid or flexible and may be positioned a predefined distance above the substrate 402 that is sufficient to ensure that the digitally tunable capacitor is OFF when the capacitor is not being actuated.

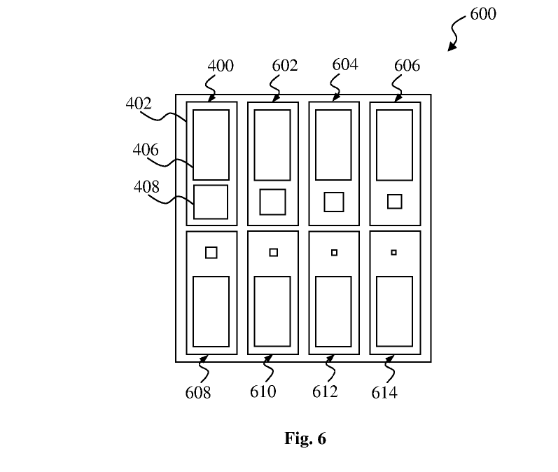

With additional reference to FIGS. 6a and 5b, a side view of the digitally tunable capacitor 400 of FIG. 4 is provided. A second actuator plate 502 and a movable capacitor plate 504 are illustrated on the underside of the cantilever 404. The second actuator plate 502 is positioned above the actuator plate 406 and the movable capacitor plate 504 is positioned above the stationary capacitor plate 408. Each capacitor plate 408 and 504 may include a layer of dielectric material 508, 506, respectively, to separate the two dielectric plates when the cantilever is actuated. It is understood that the dielectric material may be formed on a single one of the capacitor plates 408 and 504, rather than on both plates.

Referring specifically to FIG. 5b, when the cantilever 404 is actuated, the distance between the capacitor plates 408 and 504 is reduced until the dielectric layers 508 and 506 are in contact. This position turns the digitally tunable capacitor 4000N and enables it to contribute its capacitive value to an impedance matching network. Depending on the particular implementation of the MEMS, the actuation plates 406 and 502 may operate based on electrostatic, thermal, magnetic, piezo driven, or other mechanisms.

Referring to FIG. 6, one embodiment of a digitally tunable impedance network 600 is illustrated. The present example uses multiple MEMS as described with respect to FIG. 4, with the digitally tunable capacitor 400 of FIG. 4 serving as the largest capacitor in the digitally tunable impedance network 600. As can be seen by the decreasing size of each of the stationary capacitive plates, the capacitors 400, 602, 604, 606, 608, 610, 612, and 614 decrease in size from the largest digitally tunable capacitor 400 to the smallest digitally tunable capacitor 614. As there are a total of eight digitally tunable capacitors, the digitally tunable impedance network 600 may be represented by eight bits, as described previously. It is understood that the digitally tunable capacitors may be formed on a single substrate using processing steps that occur simultaneously with respect to the various capacitors.

Although the size of each stationary capacitive plate represents the capacitive value of each of the digitally tunable capacitors in the present example (with smaller plates representing lower values), it is understood that other methods for defining the capacitance may be used. For example, rather than varying the size of the stationary capacitive plates, variations may be made to the thickness of the dielectric layer(s) (e.g., 506 and 508 of FIG. 5a) used to separate the stationary and movable capacitive plates to alter the corresponding capacitance. Additionally, larger capacitive values may be achieved by ganging multiple small capacitive plates together, for example sharing a control signal between M capacitor structures, where each capacitor structure provides K capacitance to provide a total M×K capacitance.

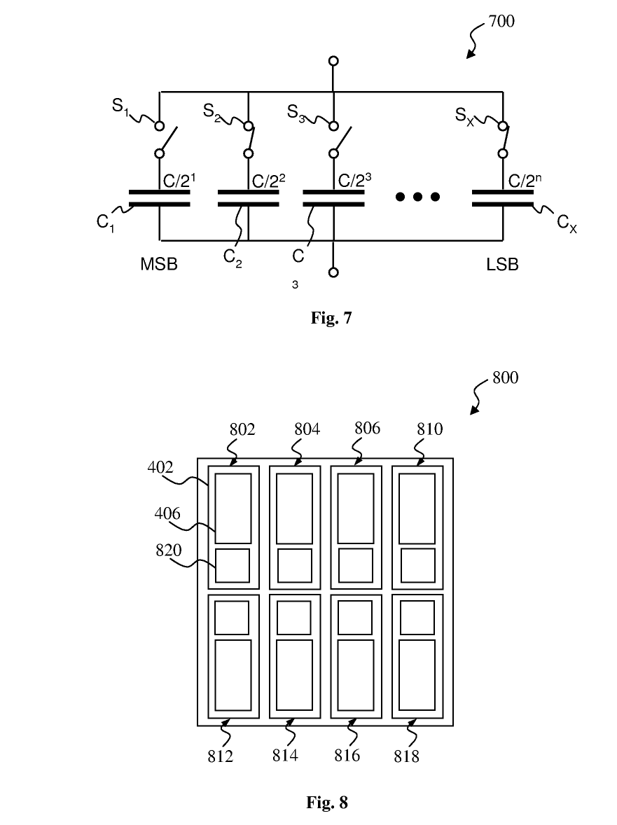

Referring to FIG. 7, a circuit 700 illustrates another embodiment of a digitally tunable matching network. In the present example, the circuit 700 is based on fixed capacitors C₁, C₂, C₃, . . . , C_{X} that may be turned either ON or OFF using corresponding switches S₁, S₂, S₃, . . . , S_{X}, respectively. Each capacitor C₁, C₂, C₃, . . . C_{X} is coupled in parallel to the other capacitors and has a predefined capacitive value that is related to the other capacitor values based on a fixed relationship. In the present example, this is a 2ⁿ relationship. More specifically, the entire capacitive network is designed to have an overall capacitive value of C when all of the capacitors C₁, C₂, C₃, . . . , C_{X} are ON. The largest capacitor in the network (C₁) has a capacitive value of C/2 (or C/2ⁿ where n=1). Each capacitor decreases in size by a factor of two and the smallest capacitor in the network (C_{X}) provides the resolution of the network. For example, if the capacitor C_{X} has a value of C/2ⁿ and n=8, then the smallest step size of capacitance allowed by the network is 1/256 of C. Therefore, the circuit 700 can provide a range of capacitances from approximately C/256 to C in steps of C/256.

In contrast to the circuit 200 of FIG. 2, the capacitors of the circuit 700 are fixed, and may be implemented using, for example, parallel plates, stacked parallel plates, interdigital fingers, or deep trench capacitors. Rather than actuating a movable plate to turn the capacitor ON or OFF, the corresponding switch may be used to close the circuit and include the capacitance provided by the associated capacitor in the impedance network. A digital controller (not shown) may be used to control the switches S₁, S₂, S₃, . . . , S_{X} using a binary format, with OFF=1 and ON=0 (or vice versa).

Referring to FIG. 8, one embodiment of a digitally tunable impedance network 800 is illustrated as an implementation of the circuit 700 of FIG. 7. The impedance network 800 uses multiple MEMS similar to those described with respect to FIG. 4 except that each MEMS forms a switch rather than a capacitor. Accordingly, rather than having two capacitive plates, the MEMS of the present example has two contacts (contact 820 is shown) that close the circuit and turn the associated capacitor ON. Because the MEMS do not determine the capacitive value of each capacitor, the contacts of the MEMS may be equally sized.

A digital controller used to control the switches S₁, S₂, S₃, . . . , S_{X} may be integrated with the MEMS on the same substrate. Alternatively, the digital controller may be separate from the MEMS.

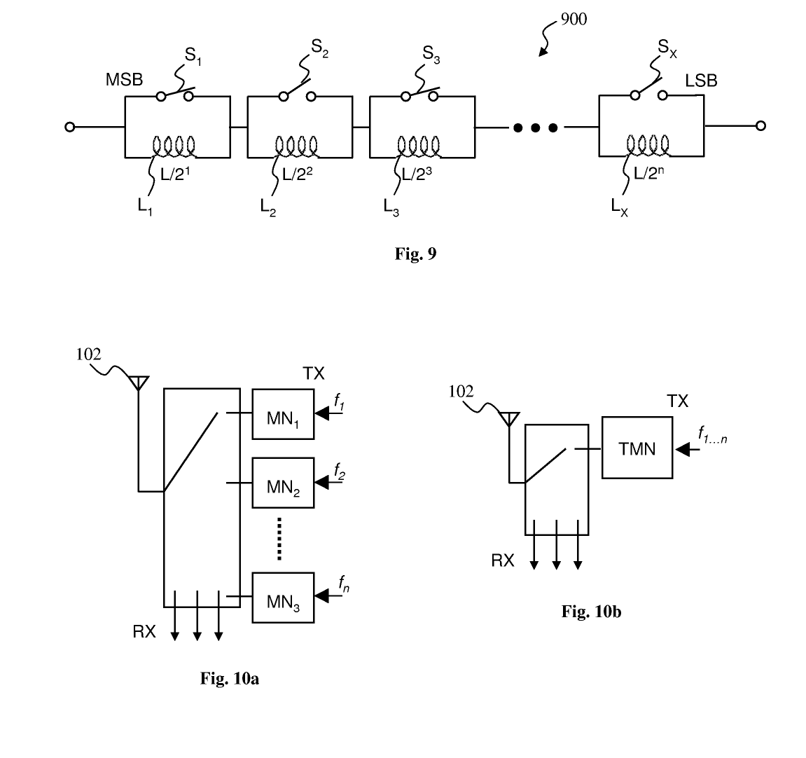

Referring to FIG. 9, a circuit 900 illustrates yet another embodiment of a digitally tunable matching network. In the present example, the circuit 900 is based on inductors L₁, L₂, L₃, . . . , L_{X} that may be turned either ON or OFF using corresponding switches S₁, S₂, S₃, . . . , S_{X}, respectively. An inductor is turned off when the switch in parallel with the inductor is closed. Each inductor L₁, L₂, L₃, L_{X} is coupled in series to the other inductors and has a predefined inductive value that is related to the other inductive values based on a 2ⁿ relationship. More specifically, the entire inductive network is designed to have an overall inductive value of L when all of the inductors L₁, L₂, L₃, . . . , L_{X} are ON. The largest inductor in the network (L₁) has an inductive value of L/2 (or L/2ⁿ where n=1). Each inductor decreases in size by a factor of two and the smallest inductor in the network (L_{X}) provides the resolution of the network. For example, if the inductor L_{X} has a value of L/2ⁿ and n=8, then the smallest step size of inductance allowed by the network is 1/256 of L. Therefore, the circuit 900 can provide a range of inductances from approximately L/256 to L in steps of L/256. It is understood that L may be selected to be a slightly larger value than desired for the total inductance, as the above example may actually provide a maximum inductance of L−(L/256), rather than L.

The inductors of the circuit 900 have fixed values and, to turn an inductor ON or OFF, the corresponding switch S₁, S₂, S₃, . . . , S_{X} may be used. One or more digital controllers may be used to control the switches S₁, S₂, S₃, . . . , S_{X} and the controller may be integrated with the MEMS on the same substrate. Alternatively, the controller may be separate from the MEMS.

Referring to FIGS. 10a and 10b, one possible application for a digitally tunable impedance matching network is in a multi-band environment. As is known, reactance (both capacitive and inductive) varies based on the frequency of a signal. Accordingly, as illustrated in FIG. 10a, a multi-band device that handles the transmission of multiple frequencies f₁, f₂, . . . , fₙ may include multiple impedance matching networks MN₁, MN₂, . . . , MN_{N} to handle the various frequencies. However, as illustrated in FIG. 10b, a single digitally tunable impedance matching network TMN may be substituted for the multiple impedance matching networks MN₁, MN₂, . . . , MN_{N} while enabling the multi-band device to handle the multiple frequencies. It is understood that some embodiments may use multiple digitally tunable impedance matching networks to achieve a desired impedance matching capability. For example, one digitally tunable impedance matching network may be used for a first range of frequencies, and another digitally tunable impedance matching network may be used for a second range of frequencies.

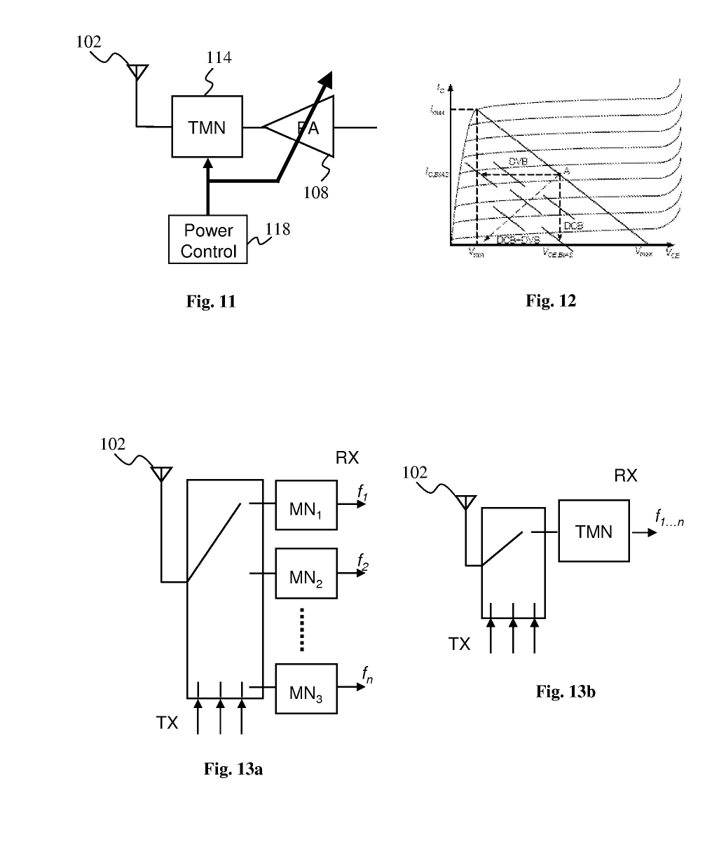

Referring to FIGS. 11 and 12, a digitally tunable impedance matching network TMN may be used for impedance matching in a variable load line environment. In the present example, a power control module provides input to both the PA 108 and the digitally tunable impedance matching network TMN 114. As is known, the drain bias of a power amplifier is generally coordinated with a signal envelope by altering the drain current and/or drain voltage, which may change the optimal load of the PA. As illustrated in FIG. 12, the load line may shift based on current, voltage, or a combination thereof. To address this shift, the digitally tunable impedance matching network TMN may be used to change the PA's load and optimize the PA's performance.

Referring to FIGS. 13a and 13b, one possible application for a digitally tunable impedance matching network is in a multi-band environment. As is known, reactance (both capacitive and inductive) varies based on the frequency of a signal. Accordingly, as illustrated in FIG. 13a, a multi-band device that handles the reception of multiple frequencies f₁, f₂, . . . , fₙ may include multiple impedance matching networks MN₁, MN₂, . . . , MN_{N} to handle the various frequencies. However, as illustrated in FIG. 13b, a single digitally tunable impedance matching network TMN may be substituted for the multiple impedance matching networks MN₁, MN₂, . . . , MN_{N} while enabling the multi-band device to handle the multiple frequencies. It is understood that some embodiments may use multiple digitally tunable impedance matching networks to achieve a desired impedance matching capability. For example, one digitally tunable impedance matching network may be used for a first range of frequencies, and another digitally tunable impedance matching network may be used for a second range of frequencies.

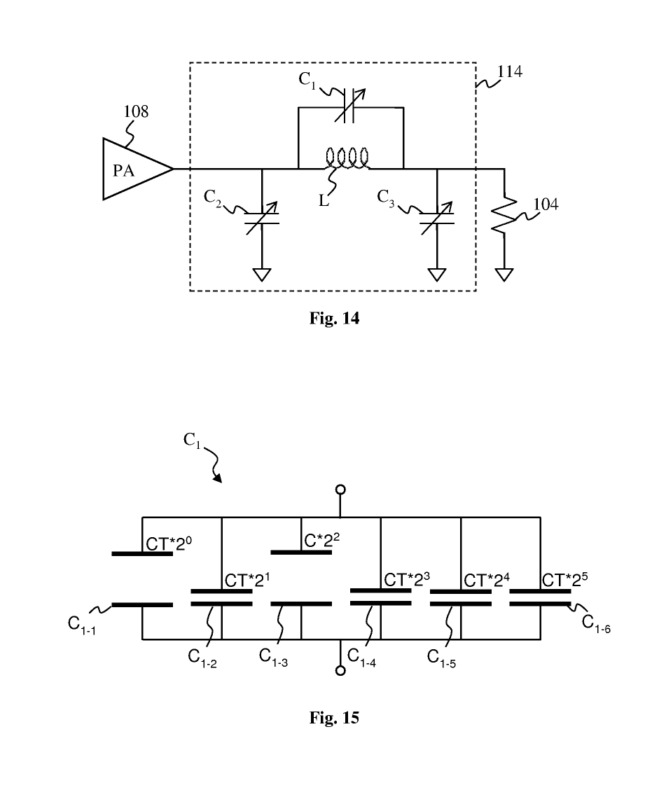

Referring to FIG. 14, in another embodiment, a more detailed example of a PA (e.g., the PA 108 of FIG. 11) with a coupled TMN (e.g., the TMN 114 of FIG. 11) is illustrated. In the present example, the TMN 114 includes digitally tunable capacitors C₁, C₂, and C₃ that may each be composed of multiple capacitor elements configured to switch between an ON state and an OFF state (i.e., as previously described with respect to FIG. 2, and an inductor L (which may be fixed or variable). The TMN 114 is positioned between the PA 108 and a variable load (e.g., the FEM 104 of FIG. 1). As described with respect to FIG. 1, TMN 114 may be used to perform impedance matching between the FEM 104 and PA 108 as the load impedance seen by the PA 108 may vary.

One issue faced when implementing a multi-band wireless device (e.g., a multi-band radio) is how to achieve optimum performance from the transmitter power amplifier (i.e., the PA 108) over a broad frequency range. The linearity performance and power added efficiency (PAE) of the PA 108 is heavily dependent on the complex load impedance presented to the PA. Based on the characteristics of the semiconductor device forming the PA 108, a specific complex load impedance or narrow range of load impedance values will provide the optimum PAE. However, the optimum output power may be achieved at a specific complex load impedance that is at a different impedance value than that required to achieve optimum PAE. Furthermore, the optimum linearity performance in terms of error vector magnitude (EVM), adjacent channel power ratio (ACPR), or two tone intermodulation ratio (TTIR) is achieved at another possibly different load impedance than that required to achieve optimum PAE or optimum output power. Since the final PA in a radio transmitter is the dominant factor in the overall power consumption, efficiency, and linearity of the transmitter, it is normally desirable to transform the actual impedance of the load through a matching network to present the ideal load impedance to the PA depending on which performance parameter is to be optimized.

A complicating factor in achieving optimum performance of the PA 108, whether over multiple bands or a single broad band, is that the ideal load impedance of the PA is often different at different frequencies. Not only does the ideal load impedance of the PA 108 change as a function of operating frequency, but the impedance of the load and the characteristics of a fixed matching network change with frequency. As a result, it is often difficult to achieve optimum PA performance over a percentage bandwidth of greater than five percent to ten percent using a fixed matching network.

The unmatched semiconductor device of a PA circuit may provide operation over many octaves of bandwidth. Accordingly, the aspect of a PA circuit that limits the optimum circuit bandwidth may be the capability to match the frequency dependent complex impedance characteristics of the device into the load over a wide range of frequencies. While it may be possible to design a fixed complex impedance matching circuit that could provide more broadband matching of the PA, the circuit would likely need several impedance transformation stages in order to track the often complex frequency function of the PA device. Since a fixed matching circuit is typically constructed of lumped element inductors and capacitors and distributed transmission line sections and since each of these elements has a finite loss due to the inherent resistive aspects, each element or stage of such a fixed matching circuit can add insertion loss. As any insertion loss between the PA and the load reduces the power delivered to the load and the overall PAE, it is generally not practical to implement a fixed complex multi-stage matching network due to the inherently higher insertion loss. While the bandwidth of optimum PA performance can be broadened in this manner, the higher insertion loss of a fixed complex matching circuit reduces the power delivered to the load at most or all of the operating frequencies.

Accordingly, the digital TMN 114 may be used to adjust for variations in the load 104. With respect to the PA 108, the TMN 114 may provide a number of advantages compared to tunable matching networks that use diode or semiconductor switches to switch various reactive elements (capacitors and inductors) either in or out of a matching circuit. For example, in a tunable matching network using diodes or semiconductor switches, the number of possible matching circuit states is limited by the number of diodes that can practically be implemented in the circuit. As the number of diodes or switches increases, so does the circuit size, cost, and insertion loss. Furthermore, the use of a semiconductor switch or diode as a switching element in a PA matching network may degrade the overall transmitter EVM, ACPR, and TTIR due to the non-linearities present in such switches and diodes.

With respect to the PA 108, the TMN 114 may also provide a number of advantages compared to tunable matching networks that use variable capacitance elements such as varactor diodes. In a tunable matching circuit implemented with variable capacitors such as varactor diodes, the diodes' capacitance can be infinitely variable over a narrow range. While this may eliminate the need for switched reactance arrays and provide greater resolution to find the ideal matching value, such matching circuits based on varactor diodes or other infinitely variable elements have certain limitations that make them undesirable. For example, the relationship of capacitance to control voltage or current is often not constant with temperature or frequency, which may result in poor setting accuracy and repeatability. In addition, any noise on a control line may result in a modulation of the reactance, which in turn results in additional carrier phase noise and degraded EVM. Furthermore, since the envelope voltage of the modulated carrier from the PA can easily reach levels comparable to the DC control voltage, additional non-linearity may be caused by a detuning of the network at peaks of the modulated carrier envelope. Also, the variable capacitor elements induce nonlinearities due to saturation or compression of the semiconductor device that further degrade the waveform EVM.

With additional reference to FIG. 15, the use of a TMN 114 formed by variable capacitor elements constructed of MEMS devices addresses these issues when coupled to the PA 108 through the activation and/or deactivation of various capacitor elements forming each capacitor C₁-C₃. In the example of FIG. 14, the quantity of individual switched MEMS elements in each of the capacitors C₁-C₃ may be from four to eight, but it is understood that other quantities may be used.

For example, as illustrated in FIG. 15, the capacitor C₁ may be formed by six capacitor elements C₁₋₁—C₁₋₆ (each of which is itself a capacitor) that together form a binary array. The first capacitor element C₁₋₁ has an actuated value of CT (which is 0.25 pf in the present example), and each following capacitor has a value of CT*2^{X+1} compared to the preceding capacitor element. Accordingly, with CT=0.25×20, the second capacitor element C₁₋₂ has an actuated value of 0.5 pf (0.25×21), the third capacitor element C₁₋₃ has an actuated value of 1.0 pf (0.25×22), the fourth capacitor element C₁₋₄ has an actuated value of 2.0 pf (0.25×23), the fifth capacitor element C₁₋₅ has an actuated value of 4.0 pf (0.25×24), and the sixth capacitor element C₁₋₆ has an actuated value of 8.0 pf (0.25×25).

The six capacitor elements C₁₋₁—C₁₋₆ may be arrayed in a parallel circuit as shown and can be individually actuated. When actuated, each capacitor element C₁₋₁—C₁₋₆ sets itself to its respective fixed value state. When not actuated, each capacitor element C₁₋₁—C₁₋₆ has a negligibly small capacitance. By controlling each element of this capacitor array individually using digital control, it is possible to select a capacitor value from 0 pf to 15.75 pf in increments of 0.25 pf. For example, in FIG. 14B, the capacitor elements C₁₋₁ and C₁₋₃ are not actuated and the remaining capacitor elements C₁₋₂ and C₁₋₄—C₁₋₆ are actuated, resulting in a capacitive value of 14.5 pf. In this example, the capacitor elements within a capacitor bank are arrayed in increasing multiples of two, but it is understood that the capacitor values may be any combination of values.

The use of the TMN 114 and its MEMS capacitors with the PA 108 provides a TMN that is digitally controlled to achieve finite states so there is little or no variability in the capacitance setting and little or no susceptibility to phase modulation due to noise on the control lines. Accordingly, the repeatability is very high. Furthermore, since the MEMS capacitor elements of each capacitor C₁-C₃ are physical capacitors, their capacitance has a low dependency on the RF power and the capacitors are not highly susceptible to non-linearities or modulation from the waveform envelope, which results in little or no EVM degradation. Also, by implementing a matching circuit consisting of MEMS capacitor arrays, a wide tuning range can be achieved. The matching circuit insertion loss is minimized since the achievable capacitor Q is very high. In the present embodiment, the lack of semiconductor switches or diodes eliminates the added insertion loss or linearity degradation that could be caused by such devices.

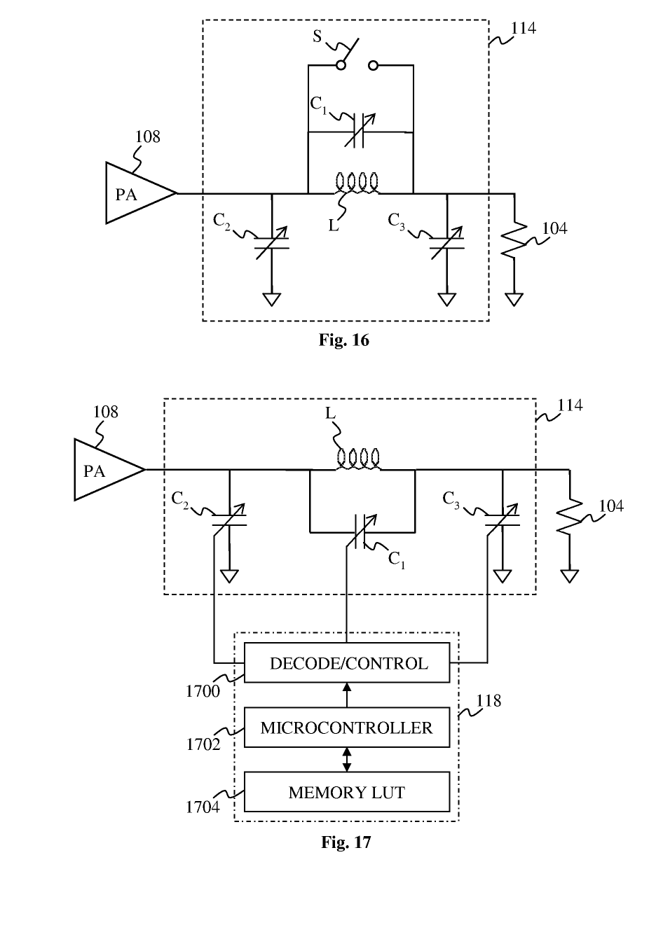

Referring to FIG. 16, another embodiment of a TMN (e.g., the TMN 114 of FIG. 11) is illustrated as coupled to a PA (e.g., the PA 108 of FIG. 11) and a variable load (e.g., the FEM 104 of FIG. 1). In the present example, the TMN 114 includes digitally tunable capacitors C₁, C₂, and C₃ and an inductor L as described with respect to FIG. 14. The TMN 114 of the present example also includes a MEMS switch S such as is described above with respect to FIG. 8. The MEMS switch S may be used to control whether the capacitor C₁ is included in or excluded from the TMN 114. For example, closing the switch S (e.g., placing the switch S into a CLOSED state) may exclude the capacitor C₁ from the total capacitance provided by the TMN 114, while opening the switch S (e.g., placing the switch S into a OPEN state) may include the capacitor C₁ in the total capacitance provided by the TMN. Although not shown, it is understood that one or more of the components of TMN 114 (i.e., digitally tunable capacitors C₁, C₂, and C₃ and inductor L) may be associated with a switch.

Referring to FIG. 17, in another embodiment of the TMN 114 of FIG. 14, a controller (e.g., the controller 118 of FIG. 11) may include a decode/control block 1700, a microprocessor 1702, and a memory look-up table (LUT) 1704 to determine and set values in the TMN for an ideal matching circuit. For example, the ideal matching circuit setting may be determined for each frequency of operation and each band for the PA circuit by searching through the various tunable elements' states while measuring performance of the PA 108. These capacitor settings or other tunable element states can then be stored in a memory device in the form of the LUT 1704 indexed by frequency, temperature, and/or other variables. Then, when a specific frequency of operation is selected (assuming a LUT having a frequency index), the microprocessor 1702 may determine the matching circuit settings from the LUT 1704 and program the TMN 114 with these settings.

Accordingly, the controller 118 may use predefined configurations to tune one or more elements of the TMN 114 based on PA characteristics during various operating conditions. It is understood that the settings stored in the LUT 1704 may be determined in different ways, such as through simulation or experimentation.

In some embodiments, the microprocessor 1702 may be implemented in firmware using an existing microprocessor (e.g., a terminal processor) in the mobile device. For example, the microprocessor 1702 may need information on the operating band, frequency, etc., and the terminal processor may already have access to such information. Furthermore, the terminal processor may also have access to non-volatile memory, so the LUT 1704 may be stored in this memory. However, it is understood that other embodiments may be used where, for example, the microprocessor 1702 and/or LUT 1704 are separate from the terminal processor. In still other embodiments, configurations may be downloaded from a network and stored in the LUT 1704 or used dynamically after downloading.

Since the MEMS capacitor array forming the TMN 114 has a wide tuning range and high repeatability, it can be used to construct a wideband PA circuit that is able to achieve optimum performance at any designated operating frequency that has been pre-calibrated into the LUT 1704.

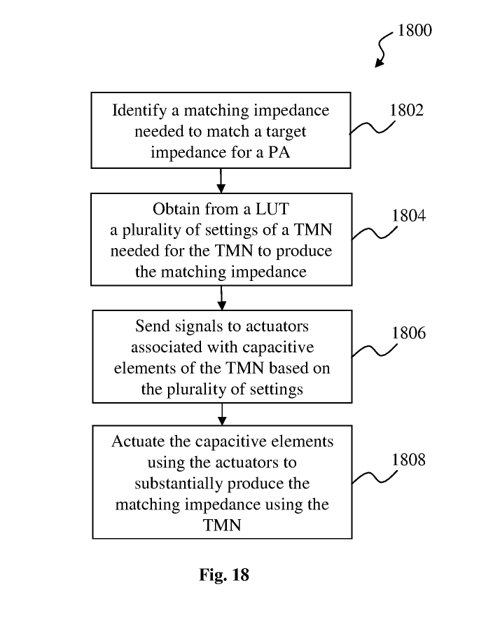

Referring to FIG. 18, in another embodiment, a method 1800 may be used with the TMN 114 of FIG. 17 to provide impedance matching for the PA 108. In step 1802, a matching impedance that is needed to match a target impedance (e.g., the impedance of the load 104) for the PA 108 is identified. In step 1804, settings that are needed for the TMN 114 to produce the matching impedance are obtained from the LUT 1706. In step 1806, signals are sent actuators associated with capacitive elements of the TMN 114 based on the settings to actuate the appropriate capacitive elements. In step 1808, the capacitive elements are actuated using the actuators to substantially produce the matching impedance using the TMN 114.

It is understood that, although the examples described above use a factor of two for purposes of illustration, other factors may be used. In addition, other number systems other than binary may be desirable in certain circumstances. Accordingly, while a factor of two in a binary system where n increases in integer steps provides certain conveniences, other relationships may be used instead and the present disclosure should not be limited to the specific illustrations provided. Furthermore, the numbers need not be sequential in every case (e.g., 2¹, 2², 2³) as the use of non-sequential patterns (e.g., 2², 2⁴, 2⁶, 2⁷) may provide benefits in some implementations. In addition, the sizes and ratios used herein (e.g., ½, ¼) may be varied based on factors such as design parameters and manufacturing criteria, and are understood to be approximate due to inconsistencies in manufacturing processes and similar issues. It is also understood that a digitally tunable impedance matching network may combine capacitive and inductive elements described above in one network.

Although some embodiments may or may not have some or all of the advantages listed below, the present disclosure may provide various advantages through the use of digitally tunable impedance matching networks. For example, quantized values of tunable capacitors and inductors may improve the accuracy and repeatability of digitally tunable impedance matching networks. For example, an array of eight capacitors configured in a binary array of octave steps provides a capacitive tuning range of seven octaves in two hundred and fifty-six steps. The settable range, accuracy, and repeatability of such a capacitor array may exceed that of a component such as a varactor diode. The flexibility in design and component requirements may enable digitally tunable impedance matching networks to match a wide range of impedances. As each component's contribution may be quantized, either fully in-circuit or fully out-of-circuit, a digitally tunable impedance matching network may not introduce phase noise into a system as is often the case using a continuously-tuned analog component such as a varactor diode. The use of MEMS devices may provide high power handling capabilities and low signal transmission losses due to the high linearity and low insertion loss of a MEMS device in comparison to a component such as a varactor diode. Furthermore, the use of MEMS devices may provide the advantage of a small footprint that is desirable in cell phones and other portable electronic devices.

Although only a few exemplary embodiments of this disclosure have been described in details above, those skilled in the art will readily appreciate that many modifications are possible in the exemplary embodiments without materially departing from the novel teachings and advantages of this disclosure. Also, features illustrated and discussed above with respect to some embodiments can be combined with features illustrated and discussed above with respect to other embodiments. Accordingly, all such modifications are intended to be included within the scope of this disclosure.

What is claimed is:

1. A handset comprising:
a power amplifier;
a variable load;
a digitally tunable impedance matching network positioned between the power amplifier and the variable load, wherein the digitally tunable impedance matching network includes a first controllable capacitor having a maximum capacitance CT, wherein the first controllable capacitor has a plurality of actuable capacitive elements having differing capacitive values ranging from CT*2⁰ to CT*2^{N}, where N=>1;
a processor coupled to the digitally tunable impedance matching network and configured to actuate individual ones of the plurality of capacitive elements to produce a capacitance of CT*2⁰ to CT*2^{N}; and
a memory coupled to the processor, wherein the memory includes a plurality of predefined configurations designed for use by the processor in actuating individual ones of the plurality of capacitive elements to produce a capacitance of CT*2⁰ to CT*2^{N} in response to a current operating condition of the handset.

2. The handset of claim 1 wherein the memory includes a lookup table containing the predefined configurations, wherein each of the predefined configurations is associated with a corresponding operating condition to be compared to the current operating condition.

3. The handset of claim 2 wherein the corresponding operating condition is based on frequency.

4. The handset of claim 2 wherein the corresponding operating condition is based on temperature.

5. The handset of claim 2 wherein the corresponding operating condition is based on an operating band.

6. The handset of claim 1 wherein the variable load is a front-end module.

7. The handset of claim 1 wherein the digitally tunable impedance matching network further includes a second controllable capacitor having a maximum capacitance CT′, wherein the second controllable capacitor has a plurality of actuable capacitive elements having differing capacitive values ranging from CT*2⁰ to CT*2^{N}, where N=>1.

8. The handset of claim 7 wherein CT equals CT′.

9. The handset of claim 7 wherein CT does not equal CT′.

10. The handset of claim 7 wherein the digitally tunable impedance matching network further includes a switch having an OPEN state and a CLOSED state, wherein the switch is positioned relative to the second controllable capacitor to remove the second controllable capacitor from the digitally tunable impedance matching network when in the CLOSED state and to include the second controllable capacitor in the digitally tunable impedance matching network when in the OPEN state.

11. The handset of claim 1 wherein the digitally tunable impedance matching network further includes a switch having an OPEN state and a CLOSED state, wherein the switch is positioned relative to the first controllable capacitor to remove the first controllable capacitor from the digitally tunable impedance matching network when in the CLOSED state and to include the first controllable capacitor in the digitally tunable impedance matching network when in the OPEN state.

13. A power amplifier circuit comprising:
a power amplifier coupled to a variable load; and
a digitally tunable impedance matching network positioned between the power amplifier and the variable load, wherein the digitally tunable impedance matching network includes a first controllable capacitor having a maximum capacitance CT, wherein the first controllable capacitor has a plurality of actuable capacitive elements having differing capacitive values ranging from CT*2⁰ to CT*2^{N}, where N=>1.

14. The power amplifier circuit of claim 13 further comprising a processor coupled to the digitally tunable impedance matching network and configured to actuate individual ones of the plurality of capacitive elements to produce a capacitance of CT*2⁰ to CT*2^{N}.

15. The power amplifier circuit of claim 14 further comprising a memory coupled to the processor, wherein the memory includes a plurality of predefined configurations designed for use by the processor in actuating individual ones of the plurality of capacitive elements to produce a capacitance of CT*2⁰ to CT*2^{N} in response to a current operating condition of the handset.

16. The power amplifier circuit of claim 15 wherein the memory includes a lookup table containing the predefined configurations, wherein each of the predefined configurations is associated with a corresponding operating condition to be matched to the current operating condition.

17. The power amplifier circuit of claim 13 wherein the digitally tunable impedance matching network further includes a second controllable capacitor having a maximum capacitance CT′, wherein the second controllable capacitor has a plurality of actuable capacitive elements having differing capacitive values ranging from CT*2⁰ to CT*2^{N}, where N=>1.

18. The power amplifier circuit of claim 13 wherein the digitally tunable impedance matching network further includes a switch having an OPEN state and a CLOSED state, wherein the switch is positioned relative to the first controllable capacitor to remove the first controllable capacitor from the digitally tunable impedance matching network when in the CLOSED state and to include the first controllable capacitor in the digitally tunable impedance matching network when in the OPEN state.

19. A method for controlling a digitally tunable impedance matching network for a power amplifier in a handset comprising:
identifying a matching impedance needed to match a target impedance for the power amplifier;
obtaining a plurality of settings of the digitally tunable impedance matching network needed for the digitally tunable impedance matching network to produce the matching impedance from a look up table;
sending signals to actuators associated with capacitive elements of the digitally tunable impedance matching network based on the plurality of settings; and
actuating the capacitive elements using the actuators to substantially produce the matching impedance using the digitally tunable impedance matching network.

20. The method of claim 19 wherein the identifying is performed by a microprocessor.
